(19) United States
(12) Patent Application Publication
(10) Pub. No.: US 2026/0090009 A1
(43) Pub. Date: Mar. 26, 2026

(54) SEMICONDUCTOR DEVICE INCLUDING HIGH VOLTAGE DEVICE

(71) Applicant: Infineon Technologies Austria AG, Villach (AT)

(72) Inventors: Lars Müller-Meskamp, Dresden (DE); Fabian Geisenhof, München (DE); Franz Hirler, Isen (DE); Tom Peterhänsel, Dresden (DE); Annett Winzer, Dresden (DE); Henning Feick, München (DE)

(21) Appl. No.: 19/324,271

(22) Filed: Sep. 10, 2025

(30) Foreign Application Priority Data
Sep. 25, 2024 (DE) 102024209270.3

(51) Int. Cl. H10D 30/65; H03K 17/041; H10D 8/00; H10D 62/10; H10D 84/83

(52) U.S. Cl. CPC H10D 30/657; H10D 8/411; H10D 30/655; H10D 62/109; H10D 62/126; H10D 84/835; H03K 17/04106

(57) ABSTRACT

A semiconductor device includes a high voltage device. The high voltage device includes a central region with a first inner region. A termination area laterally surrounds the central portion and includes a first extension region. The first extension region is formed between the first inner region and a first outer region. A lightly doped base portion and the extension region form a pn junction. The central region further includes a second inner region. The second inner region and the first inner region are laterally separated and connected to different inner contact structures. Alternatively or in addition, the high voltage device further includes a second outer region, with the first outer region and the second outer region being laterally separated and connected to different outer contact structures.

### TECHNICAL FIELD

The present disclosure relates to a semiconductor device having a high voltage semiconductor element with a termination area. Examples of the present disclosure relate to gate driver circuits with active high voltage semiconductor elements electrically connected between a high voltage part and a low voltage part.

### BACKGROUND

High voltage semiconductor devices in CMOS technology (complementary metal oxide semiconductors) form an interface between standard CMOS devices with input voltages up to 5V on the one hand and industrial or consumer circuits operating with signal voltage levels above 30V on the other. Applications for such semiconductor devices exist in all kinds of power conversion and electrical drives up to the kV range, e.g., in power converters, robotics and the automotive industry. High voltage semiconductor devices typically include a low voltage part operating in a low voltage domain and a high voltage part operating in a high voltage domain. In the low voltage part, most of the signal processing is done at low operating voltage. The high voltage part operates at higher voltage level. The low voltage part and the high voltage part provide signal interfaces for power semiconductors using higher voltage levels and/or having higher current driving and sinking capability. The electric potentials of the different voltage domains can differ by several 100V up to some 1000V. An example of such a high voltage semiconductor device is a gate driver circuit. Gate driver circuits allow a microcontroller or DSP (digital signal processor) to efficiently turn on and off power semiconductor switches. Such semiconductor devices include high voltage semiconductor elements for exchanging electric power and/or electric signals between the CMOS circuits in the different voltage domains.

There is a constant need to improve signal transmission in semiconductor devices with HV semiconductor elements with little additional effort.

### SUMMARY

High voltage semiconductor devices typically include a high voltage device with a large potential transition region formed between first doping regions associated with the low voltage part and second doping regions associated with the high voltage part. LDMOS (laterally diffused metal oxide semiconductor field effect transistors) include drain extension regions extending into the potential transition region, wherein the drain extensions are not necessarily laterally diffused but may also be formed by shallow ion implantation. HV diodes include anode extension regions extending into the potential transition region. The extension regions may increase the parasitic capacitances of the HV semiconductor element and the semiconductor volume from which leakage current can be collected.

The present disclosure is related to a semiconductor device that includes a high voltage device. The high voltage device includes a central region including a first inner region. A termination area (potential transition region) laterally surrounds the central portion and includes a first extension region. The first extension region is formed between the first inner region and a first outer region. A lightly doped base portion and the extension region form a semiconductor junction. According to alternative (a), the central region further includes a second inner region, wherein the first inner region and the second inner region are laterally separated and connected to different inner contact structures. According to alternative (b), the high voltage device further includes a second outer region, wherein the first outer region and the second outer region are laterally separated and connected to different outer contact structures. The alternatives (a) and (b) can be combined.

With the inner contact structure connected to the second inner region and/or the outer contact structure connected to the second outer region, only the portion of the potential transition region including the first extension region contributes to the parasitic capacitance of the semiconductor element. Signal transmission rate between the low voltage part and the high voltage part can be increased. In addition, the junction volume from which the HV semiconductor element collects leakage current can be reduced. The inner contact structure connected to the second inner region and/or the outer contact structure connected to the second outer region form an idle device which contains redundant parts of the potential transition region and frees the HV semiconductor elements from adverse effects of the redundant parts.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B include a schematic horizontal cross-sectional view and a schematic vertical cross-sectional view of a portion of a semiconductor device in accordance with an embodiment related to a high voltage device that includes a HV semiconductor diode and an idle device.

FIGS. 1C and 1D include a schematic horizontal cross-sectional view and a schematic vertical cross-sectional view of a portion of a semiconductor device in accordance with an embodiment related to a high voltage device including a HV semiconductor diode, and idle device and an additional contact for the idle device.

FIG. 2A to 2C include a schematic horizontal cross-sectional view and two schematic vertical cross-sectional views of a portion of a semiconductor device in accordance with an embodiment related to a high voltage device including a two-part HV semiconductor diode in a back-to-back configuration.

FIGS. 3A and 3B include a schematic horizontal cross-sectional view and a schematic vertical cross-sectional view of a portion of a semiconductor device in accordance with an embodiment related to a high voltage device including an n channel LDMOS in a drain-inside and back-to-back configuration.

FIG. 4A to 4C include a schematic horizontal cross-sectional view and two schematic vertical cross-sectional view of a portion of a semiconductor device in accordance with another embodiment related to a high voltage device including two LDMOS in a drain-inside and back-to-back configuration.

FIG. 5 is a schematic horizontal cross-sectional view of a portion of a semiconductor device in accordance with an embodiment related to a high voltage device including three LDMOS in a drain-inside configuration.

FIG. 6A to 6C include a schematic horizontal cross-sectional view and two schematic vertical cross-sectional views of a portion of a semiconductor device in accordance with an embodiment related to a high voltage device including a p channel LDMOS in a source-inside and back-to-back configuration.

FIGS. 7A and 7B include a schematic horizontal cross-sectional view and a schematic vertical cross-sectional view of a portion of a semiconductor device in accordance with an embodiment related to a high voltage device including a HV semiconductor diode in a cathode-inside configuration.

FIGS. 8A and 8B include a schematic horizontal cross-sectional view and a schematic vertical cross-sectional view of a portion of a semiconductor device in accordance with an embodiment related to a high voltage device including a HV semiconductor diode in an anode-inside configuration.

FIG. 9 is a simplified circuit diagram for a bootstrap circuit that includes the HV semiconductor diode of FIG. 8A/B in accordance with an embodiment.

FIG. 10 is a schematic vertical cross-sectional view of a portion of a semiconductor device in accordance with another embodiment related to a high voltage device with field plates.

FIG. 11 is a time diagram showing the switching responses for the leakage current and the blocking voltage for the HV semiconductor diode of FIG. 10 and a comparative example for discussing effects of the embodiments.

FIG. 12 is a schematic block diagram of a gate driver circuit with LDMOS for passing differential data signals from a high-side part to a low-side part and from the low-side part to the high-side part in accordance with an embodiment.

### DETAILED DESCRIPTION

The terms “having”, “containing”, “including”, “including” and the like are open-ended, and the terms indicate the presence of certain structures, elements or features but do not preclude the presence of additional elements or features. The articles “a”, “an” and “the” include both the plural and singular, unless the context clearly indicates otherwise.

The terms “signal-connected” and “electrically coupled” include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivities form a pn junction.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The examples described herein provide a semiconductor device that includes a high voltage device. The high voltage device may include a central region including a first inner region. A termination area may laterally surround the central portion and may include a first extension region, wherein the first extension region is formed between the first inner region and a first outer region. A lightly doped base portion and the extension region may form a semiconductor junction. According to alternative (a), the central region further includes a second inner region, wherein the first inner region and the second inner region may be laterally separated and connected to different inner contact structures. According to alternative (b), the HV semiconductor element further includes a second outer region, wherein the first outer region and the second outer region may be laterally separated and connected to different outer contact structures. Alternatives (a) and (b) can be combined with each other.

Semiconducting regions of the HV semiconductor element such as the first and second inner regions, the extension region, and the first and second outer regions are doped regions formed in a semiconductor layer having a homogenous background doping. The semiconductor layer has a planar first surface at a front side and a planar second surface at a rear side. The semiconductor layer may be formed from single-crystalline silicon or another elemental semiconductor or compound semiconductor. The first and second surfaces are formed in parallel horizontal planes. A vertical orientation is orthogonal to the horizontal planes. The first inner region, the second inner region, the first outer region and the second outer region may extend from the planar first surface into the semiconductor layer.

The base portion is formed between the first inner region, the second inner region, the first extension region, the first outer region and the second outer region on a first side and the second surface on the other side. The semiconductor junction between the lightly doped base portion and the extension region can be a pn junction or a unipolar junction such as an n−/n or p−/p junction.

The central region may include further inner regions of further HV semiconductor elements. The termination area may include further extension regions of the further HV semiconductor elements and the high voltage device may include further outer regions of the further HV semiconductor elements.

The high voltage device may be a combined high voltage device including one or more HV semiconductor elements, e.g., one or more semiconductor diodes, one or more LDMOS, one or more BJTs and/or one or more JFETs, and one or more parasitic devices (idle devices) without use function. The termination area is a potential transition region for the electric potential and is capable of blocking a comparatively high voltage of more than 30 V, 100 V, or 600 V between first conductive structures in the central region and second conductive structures formed outside the termination area.

The first extension region may be shallower than the first inner region and the first outer region. The first extension region may extend from the planar first surface into the semiconductor layer or may be vertically separated from the first surface. For example, a RESURF (reduced surface field) layer having a conductivity type complementary to that of the extension region may be formed between the first surface and the first extension region. The RESURF layer may vertically separate the first extension region from the first surface. In the lateral directions, the first extension region may extend from the first inner region to the first outer region. The first extension region may form a lateral unipolar junction with one of the first inner region and the first outer region and may form a pn junction with the other one of the first inner region and the first outer region.

The lateral separation of the first inner region between the second inner region and/or the lateral separation between the first outer region and the second outer region may reduce the portion of the semiconductor volume from which a leakage current of the HV semiconductor elements of the high voltage device can be collected and/or which contributes to a parasitic capacitance of the HV semiconductor elements. Additional contacts can dissipate a portion of the leakage current and/or fix the potential of the decoupled portion of the parasitic capacitance.

According to an embodiment, a maximum vertical extension vmax of the first inner region, the second inner region, and the first outer region may be smaller than a vertical extension v0 of the semiconductor layer.

The base portion may separate the first inner region, the second inner region, the first outer region and further doped regions from a rear side surface of the semiconductor layer opposite to the front side.

According to an embodiment, the high voltage device includes a peripheral area that includes the termination area and the first outer region, wherein the peripheral area has a radial width w0, and the radial width w0 may be constant along a circumference around the center portion.

For example, an outer isolation trench structure may laterally surround the semiconducting regions of the high voltage device. The peripheral area then extends outwards from the central region to the outer isolation trench structure. For a high voltage device with a blocking capability in a range from 50 V to 600 V, the radial width w0 may be in a range from 5 μm to 100 μm. The peripheral area may include further outer regions of further high voltage semiconductor elements.

According to an embodiment, the first inner region and a first inner contact structure may form an ohmic contact and a second inner region and a second inner contact structure form an ohmic contact.

The first and second inner contact structures may consist of or include doped polycrystalline silicon, an elemental metal, a metal alloy or a metal compound.

According to an embodiment, an inner separation structure may laterally separate the first inner region and the second inner region and/or an outer separation structure may laterally separate the first outer region and the second outer region.

The inner separation structure may include a pn junction, a doped region with a conductivity type opposite to the conductivity type of the first and second inner regions, a trench structure including an insulator material, or a combination thereof. The outer separation structure may include a pn junction, a doped region with a conductivity type opposite to the conductivity type of the first and second outer regions, a trench structure including an insulator material, or a combination thereof.

According to an embodiment, the inner separation structure may include an inner separation region having a conductivity type complementary to a conductivity type of the first and second inner regions, and/or the outer separation structure may include an outer separation region, wherein the outer separation region and the first outer region have complementary conductivity types.

For example, the inner separation region and/or the outer separation region may be or include a doped region formed by implanting dopants and diffusing and activating the implanted dopants. Alternatively, a section of the base portion extending between the first and second inner regions, and/or between the first and second outer regions, from the first surface into the semiconductor layer may form the inner separation structure or the outer separation structure.

According to an embodiment, the inner separation structure may include an inner separation trench structure extending from a first surface into a semiconductor layer that includes the first inner region and the second inner region, and/or the outer separation structure may include an outer separation trench structure extending from the first surface into the semiconductor layer.

The inner separation trench structure and/or the outer separation trench structure may be or include a thermally grown shallow trench oxide or field oxide, or a trench containing a trench fill. The trench fill may include a homogenous insulating fill or an insulating liner and a fill material different from the material of the insulating liner. A maximum vertical extension v2 of the inner separation trench structure is smaller than the vertical extension v0 of the semiconductor layer.

According to an embodiment, the termination area may further include an idle region or a second extension region, wherein the second extension region is formed between the second inner region and the second outer region, and wherein an extension separation structure laterally separates the first extension region and the second extension region or the first extension region and the idle region.

The extension separation structure may include a pn junction, an extension separation region of a conductivity type opposite to the first extension region, an extension separation trench including an insulator material, or a combination thereof. The extension separation region may be or include a doping region formed by implanting dopants and diffusing and activating the implanted dopants. Alternatively, a section of the base portion extending between the first and second extension regions from the central region through the termination area may form the extension separation region. The extension insulator structure extends from the first surface into the semiconductor layer. In the lateral direction, the extension insulator structure extends between the first and second extension regions from the central region through the termination area. The extension separation trench may be or include a thermally grown shallow trench oxide, a field oxide, or a trench containing a trench fill. The trench fill may include a homogenous insulating fill or an insulating liner and a fill material different from the material of the insulating liner. A maximum vertical extension v2 of the extension separation trench may be smaller than the vertical extension v0 of the semiconductor layer.

An extension separation trench and an inner separation trench structure may directly adjoin to each other and may have the same width and vertical extension so that the extension separation trench and the inner separation trench structure form a continuous straight structure.

According to an embodiment, the high voltage device may include an insulator frame laterally surrounding a first element area including the first inner region, the first extension region and the first outer region.

The insulator frame may be a rectangular frame including the inner separation structure and the extension separation structure. The inner separation structure may include two parallel first insulator trenches laterally extending into the central region, and a second insulator trench connecting the two parallel first insulator trenches in the central region. The extension separation structure may include two parallel insulator trenches, each insulator trench extending from the outer isolation trench structure to the end face of one of the first and second insulator trenches. The extension separation structure and the inner separation structure may have the same width and length and may be directly adjoining portions of a straight insulator structure.

According to an embodiment, the central portion may be stadium-shaped and includes a rectangular section and two tapering sections on opposite sides of the rectangular section, wherein the first inner region may be formed in the rectangular section and the second inner region may be formed in at least one of the tapering sections.

The two tapering sections may be semicircular sections forming half circles with a diameter being equal to the width of the rectangular section. Semiconducting portions of one, two, three or more functional devices may be formed exclusively in the rectangular section. The shape of the semicircular sections may be approximated by straight, orthogonal line sections forming steps.

According to an embodiment, the semicircular sections may include semiconducting portions of a parasitic device, wherein an idle region may be formed in two parts of the termination area extending radially outwards from the two semicircular sections of the central portion.

The semicircular sections may contain only semiconducting portions of the parasitic device and may be devoid of semiconducting portions of the use devices.

According to an embodiment, the first inner region has a first conductivity type and the first outer region may have a complementary second conductivity type opposite to the first conductivity type.

For example, the first conductivity type is n conductivity. The first inner region and the second inner region are n conductive and the first outer region and, if applicable, the second outer region are p conductive. The first extension region is n-conductive (lightly n doped) with a lower net dopant concentration than the first inner region or p− conductive (lightly p doped) with a lower net dopant concentration than the first outer region. The first inner region forms the cathode and the first outer region forms the anode of a functional diode, e.g., a bootstrap diode or desaturation diode for a gate driver circuit. The second inner region forms the cathode and the second outer region forms the anode of an accessible parasitic diode.

According to another example, the first conductivity type is p conductivity. The first inner region and the second inner region are p conductive and the first outer region and, if applicable, the second outer region are n conductive. The first extension region is n-conductive with a lower net dopant concentration than the first outer region or p− conductive with a lower net dopant concentration than the first inner region. The first inner region forms the anode and the first outer region forms the cathode of a functional diode, e.g., a bootstrap diode or desaturation diode for a gate driver circuit. The second inner region forms the anode and the second outer region forms the cathode of a controllable parasitic diode.

According to an embodiment, the high voltage device may include an inner separation structure radially separating the first inner region and the second inner region.

For example, the first inner region is stadium-shaped and includes a rectangular section and two semicircular sections, e.g., half circles on opposite sides of the rectangular section. The inner separation structure may form a ring of uniform width around the first inner region. The ring includes two parallel straight sections and two half circles connecting the ends of the two parallel straight sections. The second inner region may form a further ring of uniform width around the first inner region and the inner separation structure. The further ring includes two parallel straight sections and two half circles connecting the ends of the two parallel straight sections.

According to an embodiment, an outer separation structure may radially separate the first outer region and the second outer region.

The first outer region may form a ring of uniform width around the termination area. The ring includes two parallel straight sections and two half circles connecting the ends of the two parallel straight sections. The outer separation structure may form a ring of uniform width along the outer edge of the first outer region. The ring includes two parallel straight sections and two half circles connecting the ends of the two parallel straight sections. The second outer region may form a further ring of uniform width around the outer separation structure. The further ring includes two parallel straight sections and two half circles connecting the ends of the two parallel straight sections.

According to an embodiment, the high voltage device may further include a first inner source region in direct contact with the first inner region, wherein the first inner source region and the first inner region have complementary conductivity, and wherein a section of the first inner region laterally separates the first extension region and the first inner source region.

For example, the first inner source region, the first extension region, and the first outer region are p conductive. The first inner region is n conductive and forms the body region of a source-inside p channel LDMOS. The n conductive first inner region (body region) laterally separates the p− conductive first extension region and the first inner source region. The first inner source region is formed by dopant implantation and diffusion and forms a p conductive well extending from the first surface into the n conductive first inner region (body region). The first inner region may laterally surround the first inner source region.

According to an embodiment, the high voltage device may further include a first outer source region in direct contact with the first outer region, wherein the first outer source region and the first outer region have complementary conductivity, and wherein a section of the first outer region laterally separates the first extension region and the first outer source region.

For example, the first outer source region, the first extension region, and the first inner region are n conductive. The first outer region is p conductive and forms the body region of a drain-inside n channel LDMOS. The p conductive first outer region (body region) laterally separates the n-conductive first extension region and the first outer source region. The first outer source region is formed by dopant implantation and diffusion and forms an n conductive well extending from the first surface into the p conductive first outer region (body region). The first outer region may laterally surround the first outer source region.

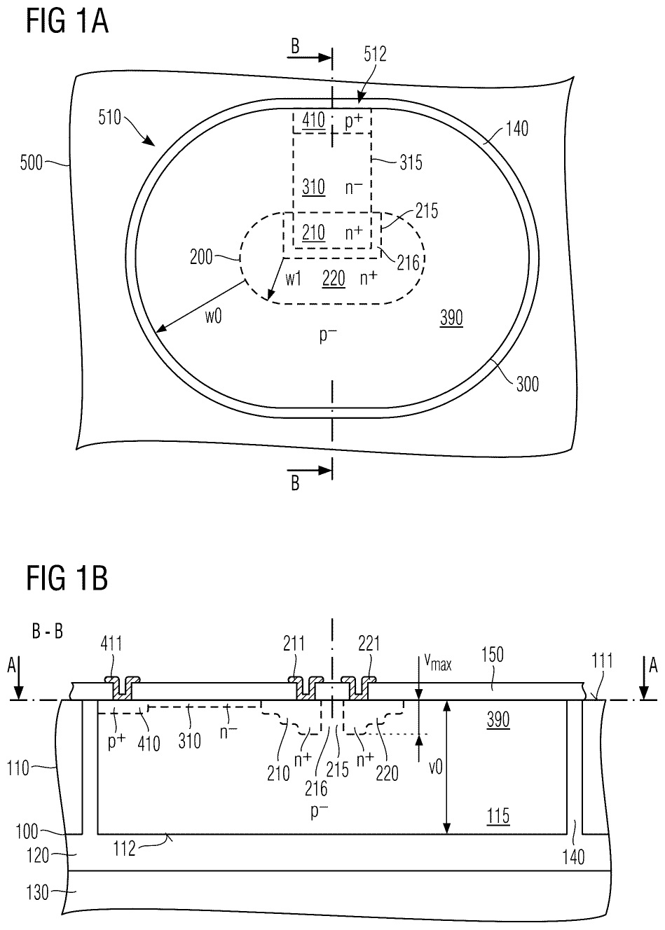

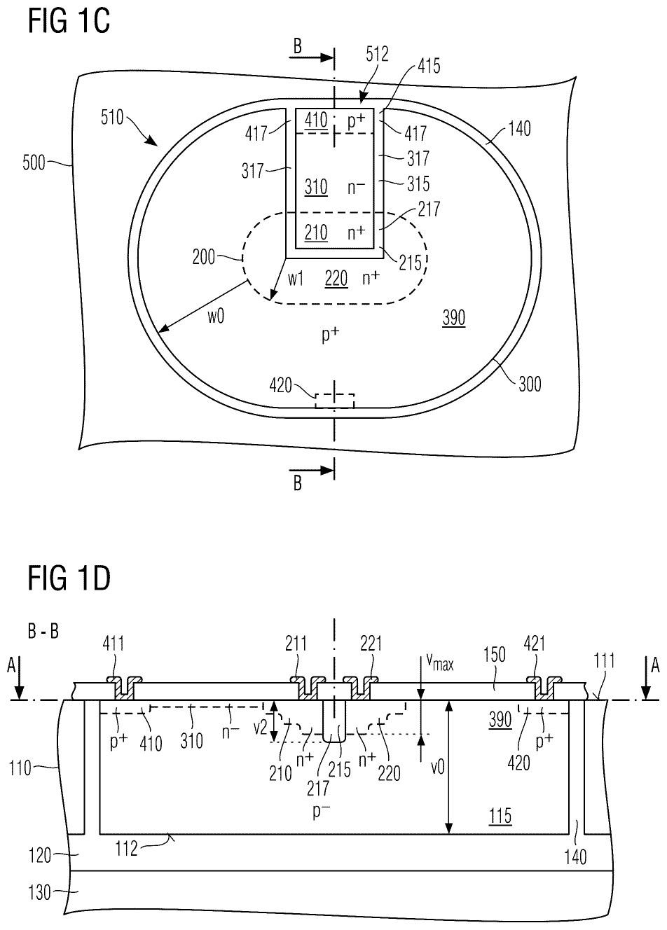

FIG. 1A and FIG. 1B show a part of a semiconductor device 500 with a high voltage device 510. The semiconductor device 500 may be a HVIC (high voltage integrated circuit), for example a gate driver circuit or a power factor correction circuit. The semiconductor device 500 includes a low voltage part with logic and analog circuits using a first supply voltage reference potential and a high voltage part with logic and analog circuits using a second supply voltage reference potential, wherein the first supply voltage reference potential and the second supply voltage reference potential may diverge from each other by more than 50V, more than 100V or more than 600V. The high voltage device 510 includes a high voltage diode that transmits an electric signals and/or electric power from the low voltage part to the high voltage part or from the high voltage part to the low voltage part.

Semiconducting regions of the high voltage device 510 are formed in a semiconductor layer 110 illustrated in FIG. 1B. The semiconductor layer 110 has a first surface 111 at a front side and a second surface 112 opposite to the front side. The first surface 111 and the second surface 112 are formed in two parallel horizontal planes. A normal to the horizontal planes defines a vertical direction. The semiconductor layer 110 includes a single-crystalline silicon layer of uniform vertical extension (thickness) between the first surface 111 and the second surface 112. Structures including other materials, e.g., insulator materials may extend from the first surface 111 into the semiconductor layer 110. A vertical extension v0 of the semiconductor layer 110 may be in a range from 10 μm to 200 μm, e.g., in a range from 35 μm to 80 μm.

The semiconductor layer 110 has a homogeneous background doping. In the illustrated example, the semiconductor layer 110 has a weak p-type (p-) background doping. In the semiconductor layer 110, doped regions may be formed by implanting dopants through the first surface 111 and activating the implanted dopants in a heat treatment. A remaining portion of the semiconductor layer 110 not affected by the implanted dopants forms a base portion 115 with the original background doping of the semiconductor layer 110.

The semiconductor layer 110 is in an SOI (silicon-on-insulator) configuration, wherein an insulator layer 120 separates the second surface 112 of the semiconductor layer 110 from a base substrate 130. The semiconductor layer 110 and the insulator layer 120 are in direct contact with each other and form a horizontal interface. A vertical extension of the insulator layer 120 may be in a range from 2 μm to 40 μm, e.g., in a range from 4 μm to 20 μm. The insulator layer 120 may be a homogeneous layer or may be a layer stack that includes at least two layers of different composition and/or structure. For example, the insulator layer 120 may include or be a semiconductor oxide layer, e.g., a silicon oxide layer. The base substrate 130 may include a weakly doped single crystalline silicon layer. The semiconductor layer 110, the insulator layer 120 and the base substrate 130 form an SOI (silicon-on-insulator) die 100.

According to FIG. 1A, the high voltage device 510 includes a central region 200 and a peripheral area laterally surrounding the central region 220, wherein the peripheral area includes a termination area 300. An outer isolation trench structure 140 laterally surrounds the peripheral area.

The central region 200 is stadium-shaped and includes one rectangular section and two semicircular sections on opposite sides of the rectangular section, wherein the radius w1 of the semicircular sections is half the corresponding side length of the rectangular section. The radius w1 may be in a range from 1 μm to 50 μm. The peripheral area laterally surrounds the central region 200 with a constant radial width w0 in the radial direction. The radial width w0 may be in a range from 5 μm to 100 μm. The outer isolation trench structure 140 extends from the first surface 111 through the semiconductor layer 110 to the second surface 112 and laterally surrounds the peripheral area at a uniform distance from the central region 200 along the entire circumference.

The central region 200 includes a first inner region 210 and a second inner region 220. An inner separation structure 215 laterally separates the first inner region 210 and the second inner region 220 from each other. In the illustrated embodiment, the inner separation structure 215 includes an inner separation region 216 having a conductivity type opposite to the conductivity type of the first and second inner regions 210, 220. A maximum vertical extension vmax of the first inner region 210 and the second inner region 220 is smaller than the vertical extension v0 of the semiconductor layer 110.

The termination area 300 includes a transition region for the electric potential and is capable of blocking a comparatively high voltage of more than 50V, 100V or 600V applied between the first inner region 210 and the first outer region 410. In the illustrated example, the termination area 300 includes a first extension region 310, a first outer region 410, and an idle region 390.

The first outer region 410 is formed along the outer isolation trench structure 140. The first extension region 310 extends in the radial direction from the first inner region 210 to the first outer region 410. The first extension region 310 is significantly shallower than the first inner region 210 and the first outer region 410. The first extension region 310 forms a vertical pn junction with the base portion 115, a lateral unipolar junction with the first inner region 210 and a lateral pn junction with the first outer region 410. In the illustrated embodiment, the first extension region 310 is in direct contact with the first surface 111. In other examples, a RESURF layer with a conductivity type opposite to the conductivity type of the first extension region 310 is formed between the first surface 111 and the first extension region 310.

Outside the first extension region 310 and the first outer region 410, the idle region 390 extends from the central region 200 to the outer isolation trench structure 140. In the illustrated example, a section of the base portion 15 forms the idle region 390, wherein the base portion and the first extension region 310 form two lateral pn junctions. Each of the lateral pn junctions forms an extension separation structure 315. The base portion 115 and the first outer region 410 form two lateral unipolar junctions.

FIG. 1B shows that the first inner region 210, the second inner region 220, the first extension region 310, the first outer region 410 and the second outer region 420 extend from the first surface 111 into the semiconductor layer 110. The base portion 115 is formed between the first inner region 210, the second inner region 220, the first extension region, the first outer region 410 and the second outer region 420 on a first side and the second surface 112 on the other side.

An interlayer dielectric 150 is formed on the first surface 111. Contact structures extend through openings in the interlayer dielectric 150 to the first surface 111, wherein a first inner contact structure 211 and the first inner region 210 form a low-resistive ohmic contact, a second inner contact structure 221 and the second inner region 220 form a low-resistive ohmic contact, and a first outer contact structure 411 and the first outer region 410 form a low-resistive ohmic contact.

The n+ doped first inner region 210, the n doped first extension region 310 and the p+ doped first outer region 410 form a high voltage diode 512 with the n+ doped first inner region 210 forming the cathode and the p+ doped first outer region 410 forming the anode. The high voltage diode 512 can be used as bootstrap diode or desaturation diode. A leakage current generated in the idle region 390 is dissipated via the second inner contact structure 221 and the first outer contact structure 411 without significantly affecting the performance of the high voltage diode 512. The lateral separation of the first inner region 210 from the second inner region 220 reduces the parasitic capacitance of the high voltage diode 512.

In the high voltage device 510 illustrated in FIG. 1C and FIG. 1D, the peripheral area between the central region 200 and the outer insulator trench structure 140 further includes a second outer region 420 of the conductivity type of the first outer region 410. The second outer region 420 is formed in direct contact with the outer insulator trench structure 140. A second outer contact structure 421 extends through an opening in the interlayer dielectric 150 to the first surface 111. The second outer contact structure 421 and the second outer region 420 form a low-resistive ohmic contact.

The inner separation structure 215 includes three straight inner separation trench structures 217 extending from the first surface 111 into the semiconductor layer 110. A first one of the straight inner separation trench structures 217 extends along the horizontal longitudinal axis of the center region 200. A second one extends from a first end of the first separation trench structure 217 in the radial direction. A third one extends from a second end of the first separation trench structure 217 in the radial direction. A vertical extension v2 of the inner separation trench structures 217 is greater than the maximum vertical extension vmax of the first and second inner regions 210, 220.

An outer separation structure 415 includes two outer separation trench structures 417 extending from the first surface 111 into the semiconductor layer 110. Each outer separation trench structure 417 laterally separates the first outer region 410 from the idle region 390. The extension separation structure 315 includes two extension insulator structures 317 extending from the first surface 111 into the semiconductor layer 110. The extension insulator structures 317 extend between the first extension region 310 and the idle region 390 in the radial direction from the central region 200 to the outer separation trench structures 417. Each inner separation trench structure 217, each extension insulator structure 317 and each outer separation trench structure 417 is a section of a linear, continuous separation trench extending in the radial direction from within the central region 210 to the outer isolation trench structure 140. In the illustrated embodiment, the separation trench is a trench containing a trench fill, wherein the trench fill includes or consist of a homogenous insulating fill.

A leakage current generated in the idle region 390 is dissipated through the second inner contact structure 221 and the second outer contact structure 412 and does not affect the performance of the high voltage diode 512. The lateral separation of the first inner region 210 from the second inner region and the lateral separation of the section of the termination area with the first extension region 310 from the idle region 390 reduce the parasitic capacitance of

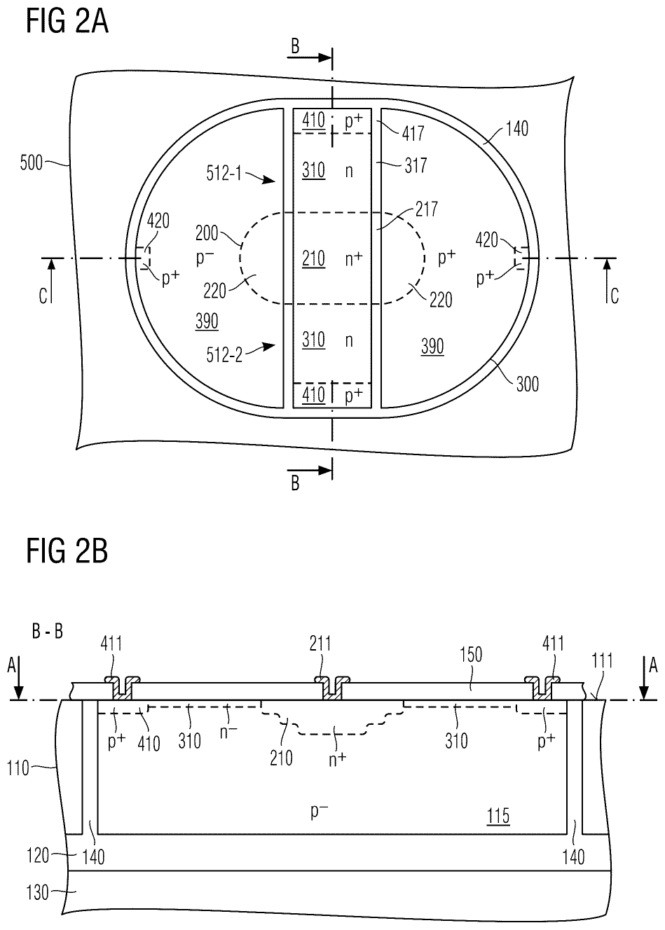

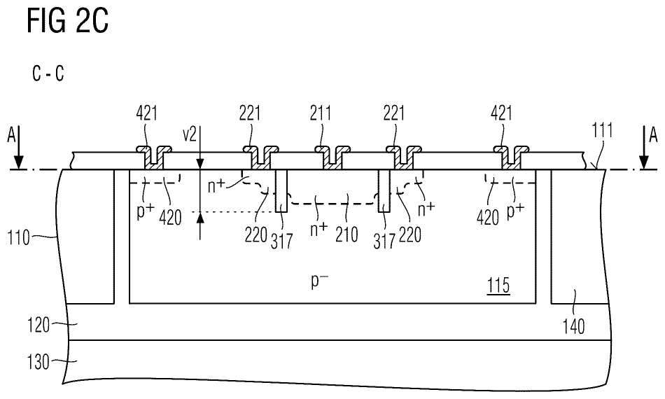

The high voltage device 510 illustrated in FIG. 2A, FIG. 2B and FIG. 2C includes a high voltage diode 512 with two sections 512-1, 512-2 formed symmetrically with respect to a horizontal longitudinal axis of the central region 200. A shared first inner region 210 is formed in the rectangular section of the central region 200. The second inner region 220 includes separated portions in the semicircular sections of the central region 200. The first extension region 310 includes two separated parts on opposite sides of the first inner region 210. The first outer region 410 includes two separated parts on opposite sides of the central region 200. The idle region 390 includes two separated parts in the semicircular sections of the peripheral area. The second outer region 420 includes two separated parts on opposite sides of the central region 200 along the outer isolation trench structure 140 and in lateral contact with the two parts of the idle region 390.

Two parallel, linear separation trenches laterally separate the first inner region 210 from the two parts of the second inner region 220, the area with the first extension region 310 from the idle region 390, and the two parts of the first outer region 410 from the idle region 390. A single first inner contact structure 211 and the first inner region 210 form an ohmic contact. Each of two first outer contact structures 411 forms an ohmic contact with one of the two parts of the first outer region 410. Each of two second inner contact structures 221 forms an ohmic contact with one of the two parts of the second inner region 220.

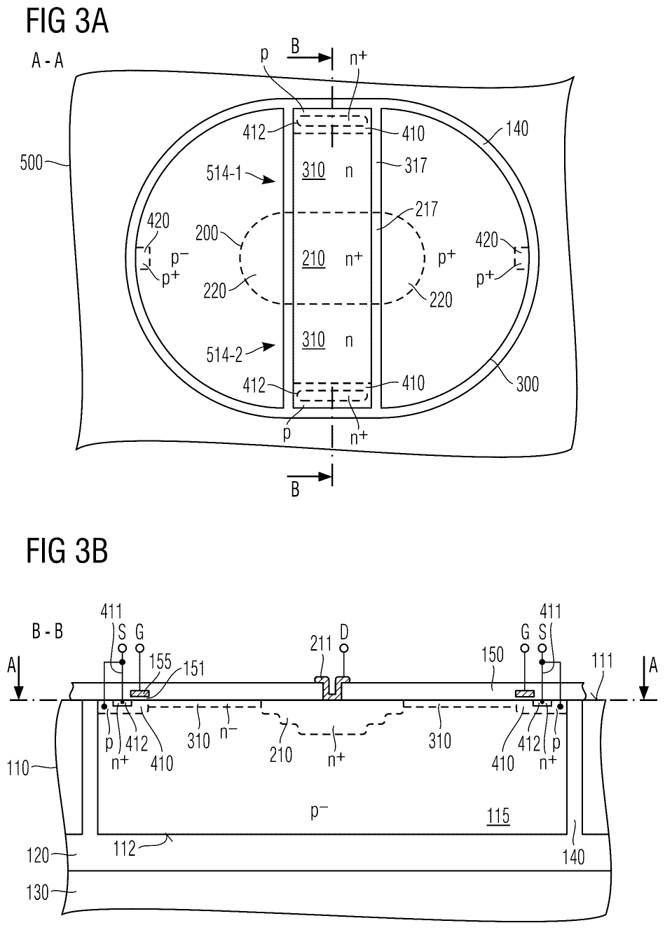

In FIG. 3A and FIG. 3B, the high voltage device 510 includes an LDMOS 514 with two sections 514-1, 514-2, which are formed symmetrically with respect to a horizontal longitudinal axis of the central region 200. The first inner region 210 is formed in the rectangular section of the central region 200. The second inner region 220 includes two separated parts in the semicircular sections of the central region 200.

The LDMOS 514 is an n-channel FET in a drain-inside configuration. The first inner region 210 forms an n+ doped drain region. The two parts of the first extension region 310 form symmetric n-doped drain extensions. The two parts of the first outer region 410 form the p doped body region. In addition, each of two parts of an outer source region 412 is formed as a well extending from the first surface 111 into one of the two parts of the first outer region 410 (body region).

On the first surface 111, a gate dielectric 159 is formed over the portions of the first outer region 410 between the two parts of the outer source region 412 and the two parts of the first extension region 310. A gate electrode 155 is formed on the gate dielectric 159. The gate electrode 155 is electrically connected to a gate terminal G. The first inner contact structure 211 is electrically connected to a drain terminal D. Each of two first outer contact structures 411 forms ohmic contacts with one part of the outer source region 412 and one part of the first outer region 410 (body region), and is electrically connected to a source terminal S.

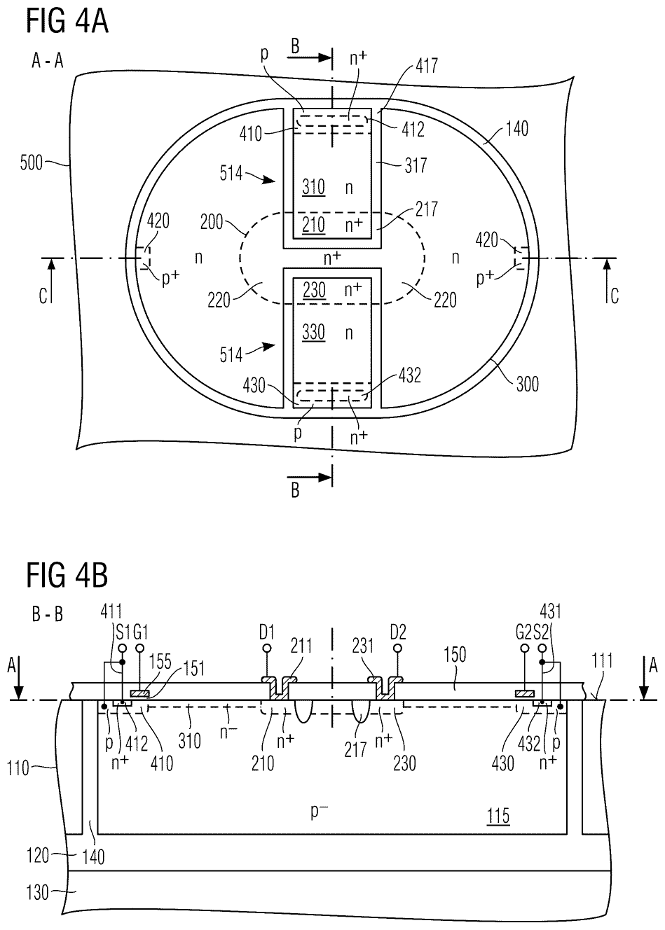

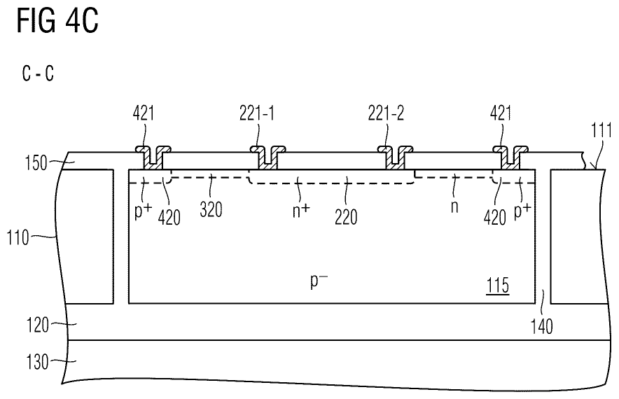

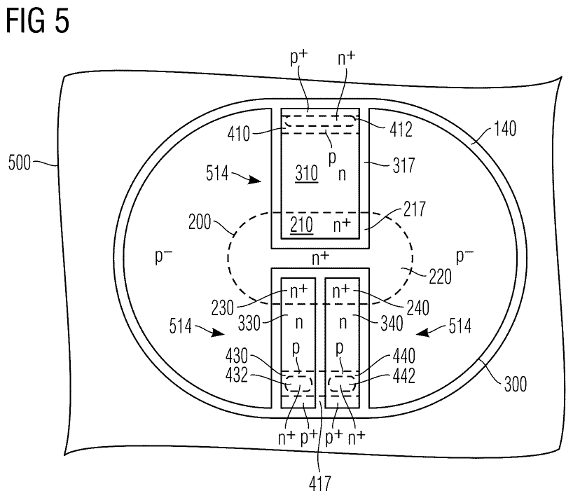

FIG. 4A and FIG. 4B show a high voltage device 510 that includes two independent LDMOS 514, which are formed symmetrically with respect to a horizontal longitudinal axis of the central region 200. A first inner region 210 of a first LDMOS 514 is formed in a first portion of the rectangular section of the central region 200. A third inner region 230 of a second LDMOS 514 is formed in a second portion of the rectangular section of the central region 200. The second inner region 220 includes two parts in the semicircular sections of the central region 200 and a third part extending between the first inner region 210 and the third inner region 230 form a first one of the semicircular sections to the second one. A first inner contact structure 211 and the first inner region 210 form an ohmic contact. The first inner contact structure 211 is electrically connected to a first drain terminal D1. A third inner contact structure 231 and the third inner region 230 form an ohmic contact. The third inner contact structure 231 is electrically connected to a second drain terminal D2.

A first outer region 410 of the LDMOS 514 is formed along a section of the outer isolation trench structure 140 in the radial direction of the first inner region 210. A first extension region 310 extends in the radial direction from the first inner region 210 to the first outer region 410. A first outer source region 412 of the first LDMOS 514 extends from the first surface 111 into the first outer region 410. A first outer contact structure 411 forms ohmic contacts with the first outer source region 412 and first outer region 410 (body region) and is electrically connected to a first source terminal S1 of the first LDMOS 514. On the first surface 111, a gate dielectric 159 is formed over the portion of the first outer region 410 between the first outer source region 412 and the first extension region 310. A gate electrode 155 is formed on the gate dielectric 159. The gate electrode 155 is electrically connected to a first gate terminal G1 of the first of the first LDMOS 514.

A third outer region 430 of the second LDMOS 514 is formed along a section of the outer isolation trench structure 140 in the radial direction of the third inner region 230. A third extension region 330 extends in the radial direction from the third inner region 230 to the third outer region 430. A third outer source region 432 of the second LDMOS 514 extends from the first surface 111 into the third outer region 430. A third outer contact structure 431 forms ohmic contacts with the third outer source region 432 and third outer region 430 (body region) and is electrically connected to a second source terminal S2 of the second LDMOS 514. On the first surface 111, a gate dielectric 159 is formed over the portion of the third outer region 430 between the third outer source region 432 and the third extension region 330. A gate electrode 155 is formed on the gate dielectric 159. The gate electrode 155 is electrically connected to a second gate terminal G2 of the second LDMOS 514.

A first separation trench structure 217, 317, 417 witch three linear sections and a section of the outer isolation trench structure 140 forms a first closed frame around the first inner region 210, the area with the first extension region 310 and the first outer region 410. A second separation trench structure witch three linear sections 217, 317, 417 and a section of the outer isolation trench structure 140 forms a second closed frame around the third inner region 230, the area with the third extension region 330 and the third outer region 430. The separation trenches may be formed as shallow trench isolators with a vertical extension greater than a vertical extension of the inner regions 210, 220, 230.

FIG. 4C shows two second inner contact structures 221-1, 221-2 forming ohmic contacts with the second inner region 220 in the two semicircular sections of the second inner region 220. The idle region 390 includes a second extension region 320 which may have the same conductivity type and dopant dose as the first extension region 310.

The high voltage device 510 shown in FIG. 5 includes three independent LDMOS 514. The first one of the high voltage FETs 514 is formed analogously to the first LDMOS 514 in FIG. 4A and FIG. 4B. The second and the third ones can be obtained by dividing in two the second LDMOS 514 in FIG. 4A and FIG. 4B along a radial line to provide a third and a fourth inner region 230, 240, a third and a fourth extension region 330, 340, a third and a fourth outer region 430, 440 and a third and a fourth outer source region 432, 442.

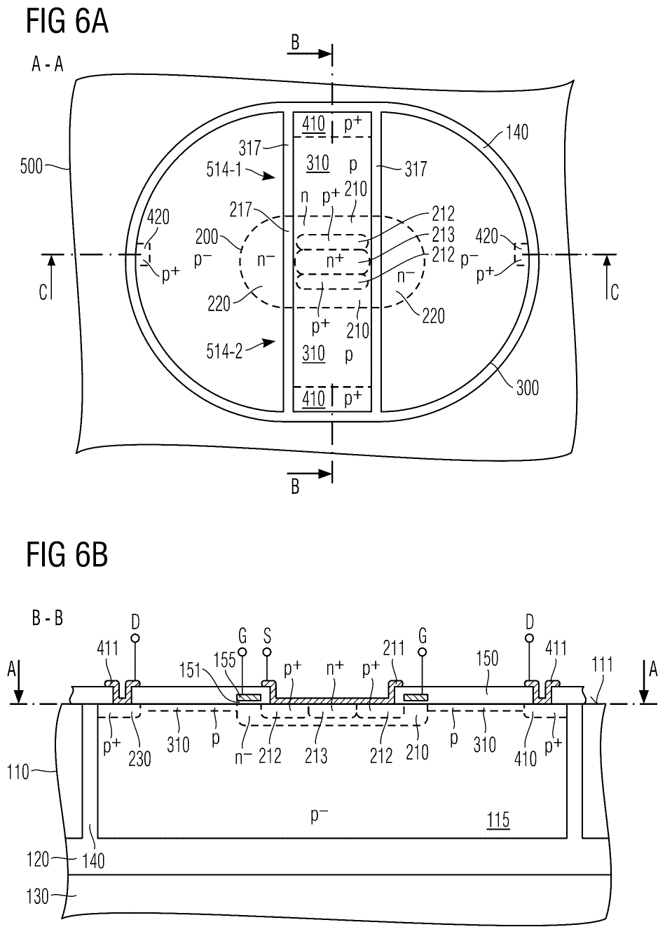

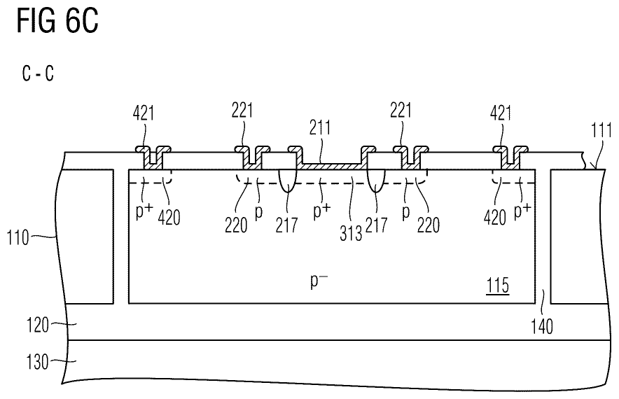

In FIG. 6A to FIG. 6C, the high voltage device 510 includes a p channel LDMOS 514 with two sections 514-1, 514-2, which are formed symmetrically with respect to a horizontal longitudinal axis of the central region 200. The first inner region 210 is formed in the rectangular section of the central region 200. The second inner region 220 includes two separated parts in the semicircular sections of the central region 200.

The LDMOS 514 has a source-inside configuration. The first inner region 210 forms an n-doped body region. Each of two parts of an inner source region 212 is formed as a well extending from the first surface 111 into the first inner region 210 (body region). A central n+ doped body contact region 213 extends from the first surface 111 into the first inner region 210. The two parts of the first extension region 310 form symmetric p− drain extensions. The two parts of the first outer region 410 form the p+ doped drain region.

On the first surface 111, a gate dielectric 159 is formed over the portions of the first inner region 210 between the two parts of the inner source region 212 and the two parts of the first extension region 310. A gate electrode 155 is formed on the gate dielectric 159. The gate electrode 155 is electrically connected to a gate terminal G. The first inner contact structure 211 forms ohmic contacts with the two parts of the inner source region 212 and the body contact region 213 and is electrically connected to a source terminal S. Each of two first outer contact structures 411 forms ohmic contacts with one part of the first outer region 410 and is electrically connected to a drain terminal D of the LDMOS 514.

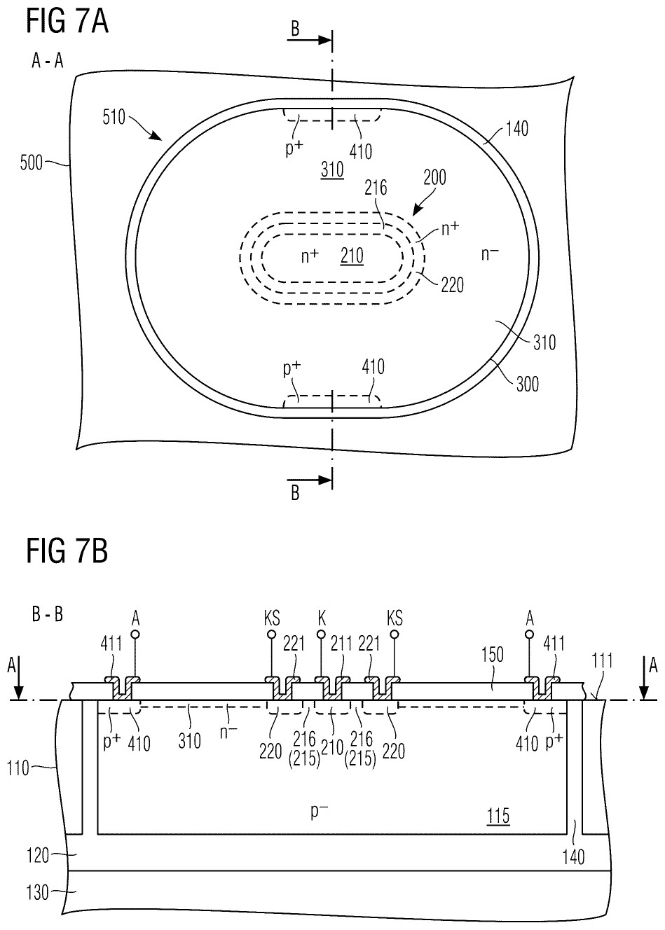

FIG. 7A and FIG. 7B show a high voltage device 510 with an inner separation structure 215 radially separating the first inner region 210 and the second inner region 220.

The first inner region 210 is stadium-shaped and includes a rectangular section and two semicircular sections, e.g., half circles on opposite sides of the rectangular section. The inner separation structure 215 forms a ring of uniform width around the first inner region 210. The ring includes two parallel straight sections and two half circles connecting the ends of the two parallel straight sections. The second inner region 220 forms a further ring of uniform width around the first inner region 210 and the inner separation structure 215. The further ring includes two parallel straight sections and two half circles connecting the ends of the two parallel straight sections. The inner separation structure 215 may be a doped region of a conductivity type opposite to the conductivity type of the first and second inner regions 210 or a section of the base portion 115.

A peripheral area between the second inner region 220 and the outer isolation trench structure 140 includes a first extension region 310 and a two-part first outer region 410. The first extension region 310 completely surrounds the second inner region 220. The first outer region 410 includes two separated parts formed in direct contact with straight sections of the outer isolation trench structure 140 and is formed symmetrically to a horizontal longitudinal axis of the high voltage device 510.

In the illustrated embodiment, the first inner region 210 and the second inner region 220 are n+ doped, the first extension region 310 is n-doped, and the two parts of the first outer region 410 are p+ doped. A first inner contact structure 211 and the first inner region 210 form an ohmic contact. The first inner contact structure 211 is electrically connected to a cathode terminal K. A two-part second inner contact structure 221 and the second inner region 220 form ohmic contacts. The two parts of the second inner contact structure 221 are electrically connected to a shield cathode terminal KS. The two parts of the first outer contact structure 411 form ohmic contacts with each of the two parts of the first outer region 410. The two parts of the first outer contact structure 411 are electrically connected to an anode terminal A.

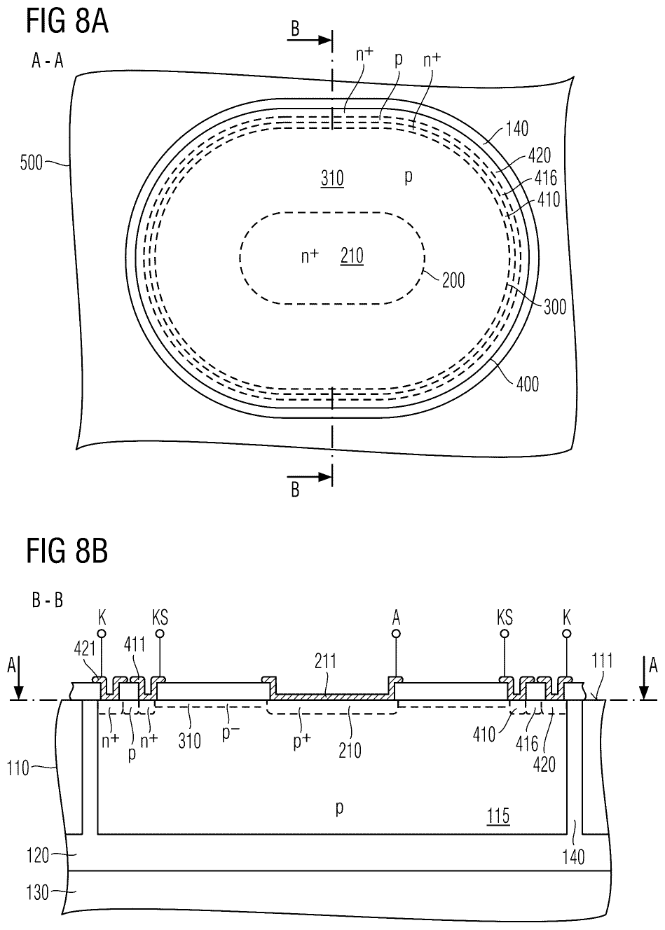

FIG. 8A and FIG. 8B show a high voltage device 510 with an outer separation structure 415 radially separating a first outer region 410 and a second outer region 420.

A central region 200 includes a first inner region 210. In the illustrated example, the first inner region 210 forms the central region 200. The termination area between the central region 200 with the first inner region 210 and the outer isolation trench structure 140 includes a first extension region 310, wherein the first extension region 310 completely surrounds the first inner region 210. The termination area further includes a first outer region 410, a second outer region 420 and an outer separation structure 415 radially separating the first outer region 410 and the second outer region 420.

The first outer region 410 forms a ring of uniform width around the first extension region 310. The ring includes two parallel straight sections and two half circles connecting the ends of the two parallel straight sections. The outer separation structure 415 forms a ring of uniform width along the outer edge of the first outer region 410. The ring includes two parallel straight sections and two half circles connecting the ends of the two parallel straight sections. The second outer region 420 forms a further ring of uniform width around the outer separation structure 415 and directly adjoins the outer insulator trench structure 140. The further ring includes two parallel straight sections and two half circles connecting the ends of the two parallel straight sections. The outer separation structure 415 may be a doped region of a conductivity type opposite to the conductivity type of the first and second outer regions 410, 420.

In the illustrated embodiment, the first outer region 410 and the second outer region 420 are n+ doped, the first extension region 310 is p-doped, and the inner region 210 is p+ doped. The first inner contact structure 211 and the first inner region 210 form an ohmic contact. The first inner contact structure 211 is electrically connected to an anode terminal A. A first outer contact structure 411 and the first outer region 410 form an ohmic contact. The first outer contact structure 411 is electrically connected to a shield cathode terminal KS. A second outer contact structure 421 and the second outer region 420 form an ohmic contact. The second outer contact structure 421 is electrically connected to a cathode terminal K.

Each of the high voltage devices 510 of FIG. 7A/7B and FIG. 8A/8B includes a high voltage main diode with the anode terminal A and the cathode terminal K and a high voltage shield diode with the anode terminal A and the cathode terminal KS.

The presence of the high voltage shield diode can reduce the leakage current of the high voltage main diode by an order of magnitude.

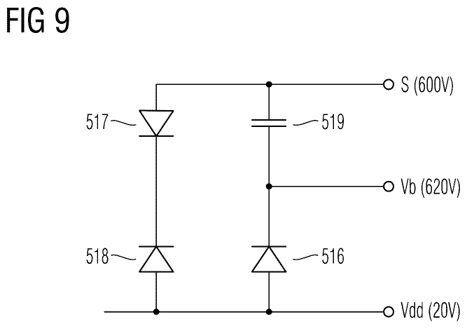

FIG. 9 shows a circuit diagram of a portion of a bootstrap circuit for a HVIC with a high voltage main diode 516 and a high voltage shield diode 518 as described with respect to FIG. 7A/7B or FIG. 8A/8B used as bootstrap diode.

The common anode of the high voltage main diode 516 and the high voltage shield diode 518 is connected to the positive supply potential of a low voltage part of the HVIC. A bootstrap capacitor 519 in a high voltage part of an HVIC is electrically connected between a switching node S and the cathode of the high voltage main cathode 516. An anode of a low voltage diode 517 is electrically connected to the switching node S. A cathode of the low voltage diode 517 is electrically connected to the cathode of the high voltage shield diode 518.

When the switching node is connected to a low potential, the high voltage main diode 512 supplies a charging current to the bootstrap capacitor 519. When the switching node S is connected to a high potential, e.g., 600V, the high voltage main diode 516 blocks. The high voltage shield diode 518 reduces the leakage current in the high voltage device the high voltage main diode 512 is part of. The low voltage diode 517 is suitable to block about 20V and blocks the high voltage shield diode 518 for the bootstrap charging time.

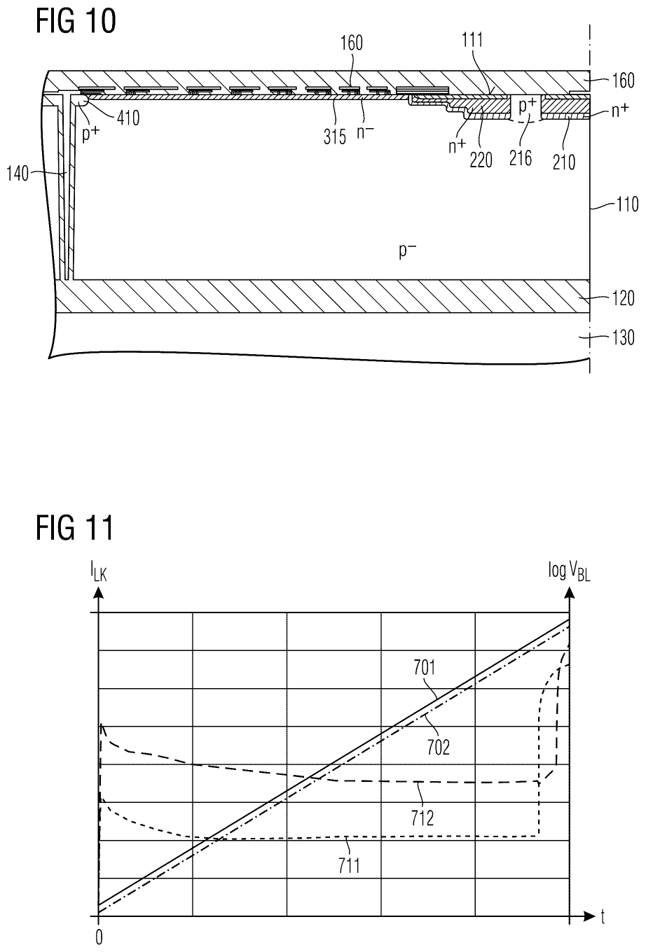

FIG. 10 shows one half of a symmetric high voltage device 510 with a central divided cathode and a common peripheral anode region. An inner separation structure 215 radially separates the first inner region 210 and the second inner region 220. The first inner region 210 forms the cathode of the high voltage main diode. The second inner region 220 forms the cathode of the high voltage shield diode. Field plates 180 are formed in the termination area above the first extension region 310.

The time diagram in FIG. 11 shows the progression of blocking voltage 701 and leakage current 711 after the high voltage device of FIG. 7A/7B with the high voltage main diode 518 and the high voltage shield diode 518 changed from the forward conducting mode to the blocking mode. Line 702 shows the progression of blocking voltage and line 712 the progression of the leakage current for a comparative example with a homogenous central region 200 without the inner separation structure 215. Dividing the central region into two separated inner regions increases the switching speed and reduces the leakage current by about a third.

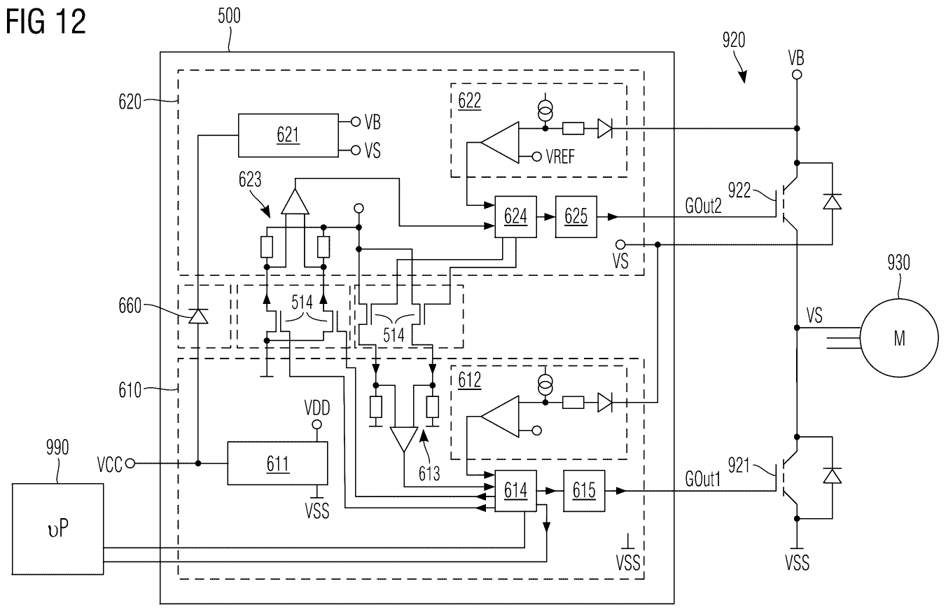

FIG. 12 shows a semiconductor device 500 configured as gate driver circuit. The gate driver circuit includes a high side part 620 configured to drive a gate of a high side switch 922 of a half bridge and a low side part 610 configured to drive a gate of a low side switch 921 of the half bridge. The semiconductor device 500 includes a high side power supply circuit 621 to obtain a positive power supply voltage VB for the high side part 620 (high side supply potential VB), wherein a bootstrap diode 660 charges a bootstrap capacitor from an external supply voltage VCC. The positive power supply voltage VB for the high side part 620 is referenced to a high side reference potential VS, which corresponds to the potential of the switching node of a half bridge 920.

A high side desaturation detection circuit 622 is connected to the supply potential VA of the half bridge 920, detects a desaturation of the high side switch 922 of the half bridge 920, and outputs a high side desaturation signal indicating whether a desaturation condition exists. A high side receiver circuit 623 receives a differential gate control signal from two field effect transistors, e.g., n channel LDMOS 514 as described above and outputs a single-ended high side gate control signal. A logic circuit 624 in the high side part 620 receives the high side desaturation signal and the high side gate control signal. The logic circuit 624 in the high side part 620 outputs a second gate drive signal GOut2 in response to the high side gate control signal provided that the high side desaturation signal does not indicate a desaturation condition. A high side driver stage 625 may drive the second gate drive signal GOut2.

The logic circuit 624 in the high side part further outputs a differential high side data signal. Two p channel LDMOS 514 as described above transmit the differential high side data signal from the high side part 620 to a low side receiver circuit 613 in the low side part 610.

The low side part 610 of the gate driver circuit includes a low side power supply circuit 611 to obtain a positive power supply voltage VDD for the low side part 610. The positive power supply voltage VDD for the low side part 610 is referenced to the first reference potential VSS.

A low side desaturation detection circuit 612 is connected to the output node of the half bridge 920, detects a desaturation of the low side switch 921, and outputs a low side desaturation signal indicating whether a desaturation condition exists. A low side receiver circuit 613 receives a differential low side data signal from the two p channel LDMOS 514 and outputs a single-ended low side data signal. A logic circuit 614 in the low side part 610 receives the low side data signal, the low side desaturation signal, and a low side gate control signal from an external source like a processor 990. The logic circuit 614 in the low side part 610 outputs a first gate drive signal GOut1 in response to the low side gate control signal provided that none of the low side desaturation signal and the low side data signal indicates a desaturation condition. A low side driver stage 615 drives the first gate drive signal GOut1.

The logic circuit 614 in the low side part 610 further outputs a differential gate control signal. The two n channel LDMOS field effect transistors 514 transmit the differential gate control signal from the low side part 610 to the high side part 620. An inductive load 930 is electrically connected between the switching nodes of two half bridges 920.

LDMOS 514 having any of the configurations of the present embodiments improve the signal transfer between the low side part 610 and the high side part 620 and can improve the performance of the half bridge 920 by allowing higher switching frequencies.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the semiconductor devices including its preferred embodiments as outlined in the present document may be used stand-alone or in combination with the other semiconductor devices disclosed in this document. In addition, the features outlined in the context of a semiconductor device are also applicable to a corresponding method, and vice versa. Furthermore, all aspects of the methods and devices outlined in the present document may be arbitrarily combined. In particular, the features of the claims may be combined with one another in an arbitrary manner.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device, comprising:
a high voltage device including:
a central region including a first inner region;
a termination area laterally surrounding the central portion and including a first extension region;
a first outer region, wherein the first extension region is formed between the first inner region and the first outer region; and
a lightly doped base portion, the base portion and the extension region forming a semiconductor junction,
wherein (a) the central region further includes a second inner region and the first inner region and the second inner region are laterally separated and connected to different inner contact structures, and/or (b) the active high voltage device further includes a second outer region and the first outer region and the second outer region are laterally separated and connected to different outer contact structures.

2. The semiconductor device of claim 1, wherein a maximum vertical extension vmax of the first inner region, the second inner region, and the first outer region is smaller than a vertical extension of the semiconductor layer.

3. The semiconductor device of claim 1, wherein a peripheral area of the high voltage device including the termination area and at least the first outer region has a radial width, and wherein the radial width is constant along a circumference around the center portion.

4. The semiconductor device of claim 1, wherein the first inner region and a first inner contact structure form an ohmic contact, and wherein the second inner region and a second inner contact structure form an ohmic contact.

5. The semiconductor device of claim 1, further comprising:
an inner separation structure laterally separating the first inner region and the second inner region, and/or an outer separation structure laterally separating the first outer region and the second outer region.

6. The semiconductor device of claim 5, wherein the inner separation structure includes an inner separation region having a conductivity type complementary to a conductivity type of the first and second inner regions, and/or the outer separation structure includes an outer separation region, and wherein the outer separation region and the first outer region have complementary conductivity types.

7. The semiconductor device of claim 6, wherein the termination area includes an idle region or a second extension region, wherein the second extension region is formed between the second inner region and the second outer region, and wherein an extension separation structure laterally separates the first extension region and the second extension region or the first extension region and the idle region.

8. The semiconductor device of claim 5, wherein the inner separation structure includes an inner separation trench structure extending from a first surface into a semiconductor layer including the first inner region and the second inner region, and/or the outer separation structure includes an outer separation trench structure extending from the first surface into the semiconductor layer.

9. The semiconductor device of claim 8, wherein the termination area includes an idle region or a second extension region, wherein the second extension region is formed between the second inner region and the second outer region, and wherein an extension separation structure laterally separates the first extension region and the second extension region or the first extension region and the idle region.

10. The semiconductor device of claim 1, further comprising:
an insulator frame laterally surrounding a first element area including the first inner region, the first extension region and the first outer region.

11. The semiconductor device of claim 1, wherein the central portion is stadium-shaped and includes a rectangular section and two tapering sections on opposite sides of the rectangular section, and wherein the first inner region is formed in the rectangular section and the second inner region is formed in at least one of the tapering sections.

12. The semiconductor device of claim 11, wherein the tapering sections include semiconducting portions of a parasitic device, and wherein an idle region (390) is formed in two parts of the termination area extending radially outwards from the two tapering sections of the central portion.

13. The semiconductor device of claim 12, further comprising:
an outer separation structure radially separating the first outer region and the second outer region.

14. The semiconductor device of claim 1, wherein the first inner region has a first conductivity type and the first outer region has a complementary second conductivity type opposite to the first conductivity type.

15. The semiconductor device of claim 14, further comprising:
an inner separation structure radially separating the first inner region and the second inner region.

16. The semiconductor device of claim 1, further comprising:
a first inner source region in direct contact with the first inner region,
wherein the first inner source region and the first inner region have complementary conductivity, and
wherein a section of the first inner region laterally separates the first extension region and the first inner source region.

17. The semiconductor device of claim 1, further comprising:
a first outer source region in direct contact with the first outer region,
wherein the first outer source region and the first outer region have complementary conductivity, and
wherein a section of the first outer region laterally separates the first extension region and the first outer source region.
